(19) United States
(12) Patent Application Publication
(10) Pub. No.: US 2024/0256224 A1
(43) Pub. Date: Aug. 1, 2024

(54) SEMICONDUCTOR DEVICE, TRUE RANDOM NUMBER GENERATOR, AND METHOD FOR FABRICATING SEMICONDUCTOR DEVICE

(71) Applicant: TAIWAN SEMICONDUCTOR MANUFACTURING COMPANY LTD., HSINCHU (TW)

(72) Inventors: JEREMY GUY, SAN JOSE, CA (US); ELIA AMBROSI, HSINCHU CITY (TW); XINYU BAO, FREMONT, CA (US)

(21) Appl. No.: 18/313,387

(22) Filed: May 8, 2023

Related U.S. Application Data
(60) Provisional application No. 63/482,577, filed on Jan. 31, 2023.

(51) Int. Cl. G06F 7/58; H01L 25/00; H01L 25/065; H01L 25/18; H10B 80/00

(52) U.S. Cl. CPC G06F 7/588; H01L 25/0657; H01L 25/18; H01L 25/50; H10B 80/00

(57) ABSTRACT

The present disclosure provides a semiconductor device, which includes a first die and a second die. The first die includes a randomness harvesting circuit. The second die includes a memory array, and the second die is vertically stacked on the first die. The memory array includes a randomness source circuit, and a true random number is generated using the randomness source circuit on the second die and the randomness harvesting circuit on the first die.

### CROSS-REFERENCE TO RELATED APPLICATIONS

This application claims the benefit of U.S. Provisional Application No. 63/482,577, filed Jan. 31, 2023, the entire disclosure of which is incorporated by reference herein.

### BACKGROUND

The present disclosure relates to memory devices, and, in particular, to a semiconductor device, a true random number generator (TRNG), and a method for fabricating a semiconductor device.

A true random number generator (TRNG) generates random numbers based on a physical phenomenon that is expected to be random, such as atmospheric noise, thermal noise, radioactive decay, shot noise, avalanche noise, or radio noise, for example. Since the physical phenomenon used as the entropy source for the TRNG is unpredictable, the generated random numbers are truly random. In contrast, pseudo-random number generators (PRNGs) use mathematical formulae or precalculated tables of random numbers to produce sequences of numbers that appear to be random, but are actually predictable and deterministic given the initial seed condition used to generate the pseudo-random numbers.

TRNG, in existing practice, relies on a ring oscillator which is integrated in the front end of the line, resulting in a larger footprint of the integrated circuit. The footprint cost of the integrated circuit can, accordingly, be reduced by integrating the ring oscillator TRNG in an external circuit, but this renders the design more vulnerable to external security attacks.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a block diagram of a semiconductor device 100 in accordance with an embodiment of the disclosure.

FIG. 2 is a diagram of a true random number generator 200 in accordance with an embodiment of the present disclosure.

FIG. 3 is a diagram illustrating relationship curves between voltage and current of a selector device in accordance with an embodiment of the present disclosure.

FIG. 4A is a schematic diagram of the randomness source circuit in accordance with a first embodiment of the present disclosure.

FIG. 4B is a waveform diagram of the signals in various nodes in the randomness source circuit in accordance with the embodiment of FIG. 4A.

FIG. 5A is a schematic diagram of the randomness source circuit in accordance with a second embodiment of the present disclosure.

FIG. 5B is a waveform diagram of the voltage V_{C} at the output terminal of the randomness source circuit in accordance with the embodiment of FIG. 5A.

FIG. 6A is a schematic diagram of the randomness source circuit in accordance with a third embodiment of the present disclosure.

FIG. 6B is a waveform diagram illustrating various signals in the randomness source circuit in accordance with the embodiment of FIG. 6A.

FIG. 7A is a block diagram of the randomness harvesting circuit 114 in accordance with an embodiment of the present disclosure.

FIG. 7B is a diagram illustrating generation of random bits from the clock signal by the edge detection circuit in accordance with the embodiment of FIG. 7A.

FIG. 8A is a block diagram of the randomness harvesting circuit 114 in accordance with another embodiment of the present disclosure.

FIG. 8B is a diagram illustrating generation of random bits from multiple clock signals by the edge detection circuit in accordance with the embodiment of FIG. 8A.

FIG. 9 is a waveform diagram of the oscillation signal and multiple clock signals in the randomness source circuit in accordance with the embodiment of FIG. 5A.

FIG. 10A is a diagram illustrating relationships between the SP800-22 measured value and clock period in accordance with the embodiment of FIG. 9.

FIG. 10B is diagram illustrating the relationships between the voltage and time using different parallel capacitors and voltages in accordance with the embodiment of FIG. 9.

FIG. 10C is a diagram illustrating relationships between the critical clock for true randomness and the oscillation variation in accordance with the embodiment of FIG. 9.

FIGS. 11A-11B are block diagrams of the true random number generator in accordance with different comparative embodiments of the present disclosure.

FIG. 12 is a flowchart of a method for fabricating a semiconductor device in accordance with an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

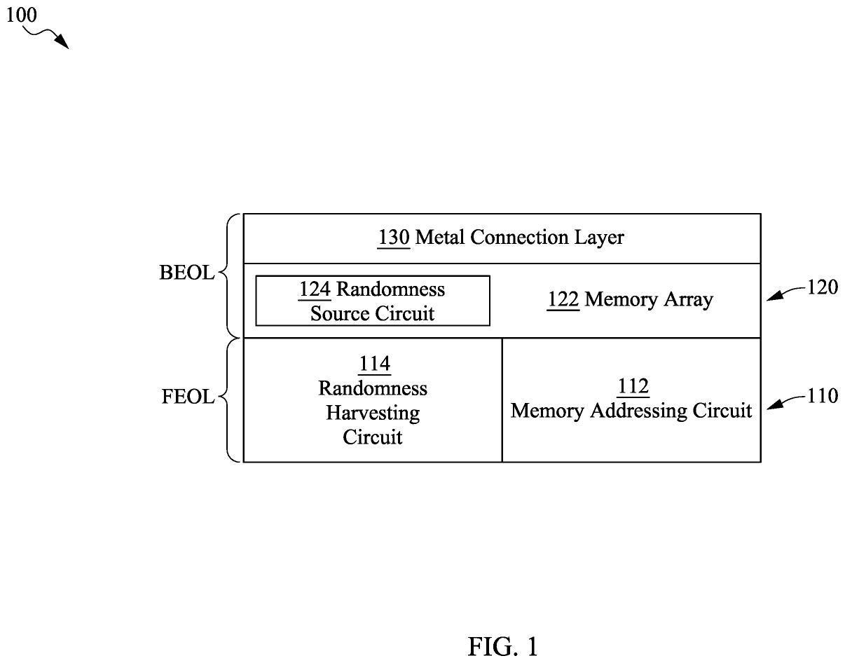

FIG. 1 is a block diagram of a semiconductor device 100 in accordance with an embodiment of the disclosure.

In some embodiments, the semiconductor device 100 can be a non-volatile memory device using one or more 3D-stacked memory arrays. In some other embodiments, the semiconductor device 100 can be part of an integrated circuit (IC) chip or system-on-chip (SoC). As shown in FIG. 1, the semiconductor device 100 may include a memory addressing circuit 112, a randomness harvesting circuit 114, a memory array 122, a randomness source circuit 124, and a metal connection layer 130.

In some embodiments, the memory addressing circuit 112 and the randomness harvesting circuit 114 may be fabricated on a first die 110 such as a logic die fabricated in the front end of line (FEOL). The memory array 122 and the randomness source circuit 124 may be fabricated on a second die 120 such as a memory die. In the back end of line (BEOL), the second die 120 is vertically stacked on and bond to the first die 110, and the stacked structure can be regarded as a 3D-stacked memory. In addition, a metal connection layer 130 is also formed on a top surface of the second die 120 in the back end of line. It should be noted that the arrangement of the randomness source circuit 124 and the randomness harvesting circuit 114 shown in FIG. 1 is for purposes of description, and part of the randomness source circuit 124 may be fabricated in the front end of line.

FEOL can be referred to as a first portion of IC fabrication process where the individual devices (such as transistors, capacitors, resistors, etc.) are patterned in the semiconductor wafer. After the last step of FEOL, there is a wafer with isolated transistors and without any wires. FEOL generally covers everything up to (but not including) the deposition of metal interconnect layers.

BEOL can be referred to as a second portion of IC fabrication process where the individual devices (such as transistors, capacitors, resistors, etc.) get interconnected with wirings (i.e., the metal layers) on the wafer. BEOL generally begins when the first layer of metal is deposited on the wafer. BEOL includes contacts, insulating layers (dielectrics), metal levels, and bonding sites for chip-to-package connections.

In some embodiments, the memory addressing circuit 112 may be an address decoding circuit that is configured to select memory cells in the memory array 122 in response to a memory address indicated by a memory command, but the present disclosure is not limited thereto. The memory array 122 may be implemented using one of non-volatile memory, such as MRAM (magnetic RAM), PCRAM (phase change RAM), RRAM (resistive RAM), flash memory, etc., but the present disclosure is not limited thereto.

The randomness source circuit 124 may be configured to generate an oscillation signal between two logic states (e.g., 0 and 1) of the semiconductor device 100. For example, the randomness source circuit 124 may be implemented using different circuits, such as a selector self-oscillation circuit, a selector-controlled oscillation circuit, or a set/reset non-volatile memory circuit, details of which will be described later. The randomness harvesting circuit 114 may be configured to convert the oscillation signal generated by the randomness source circuit 124 into a bitstream of random numbers. The randomness source circuit 124 and the randomness harvesting circuit 114 may be collectively regarded as a true random number generator (TRNG).

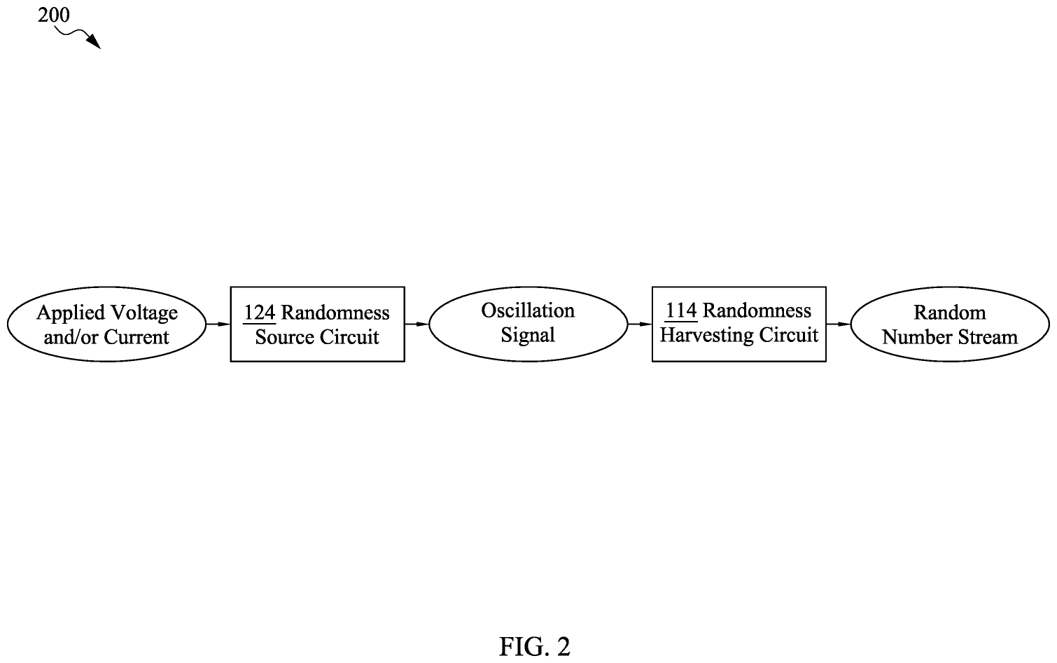

FIG. 2 is a diagram of a true random number generator 200 in accordance with an embodiment of the present disclosure. Please refer to FIG. 1 and FIG. 2.

In some embodiments, depending on the oscillation technique used by the randomness source circuit 124, when a voltage and/or current is applied to the random source circuit 124, the random source circuit 124 may generate an oscillation signal between two states of logic 0 and logic 1. The randomness harvesting circuit 114 may be provided with a clock signal (i.e., in a fixed frequency), and it can detect rising edges and/or falling edges of the oscillation signal generated by the randomness source circuit 124. For example, upon detecting a rising edge and/or a falling edge of the oscillation signal, the randomness harvesting circuit 114 may sample the provided clock signal to output a random number bit. The aforementioned operation can be repeated so as to generate a random number stream.

In some embodiments, the randomness harvesting circuit 114 may be provided with a plurality of clock signals with different frequencies, and the frequencies of the provided clock signals may satisfy some particular requirements. For example, given that a first clock signal with a first frequency and a second clock signal with a second frequency are provided to the randomness harvesting circuit 114, the second frequency may be twice (or half) the first frequency or a frequency that satisfies formula (1) described later so as to satisfy the requirement of randomness, thereby generating a true random number. If the second frequency does not satisfy formula (1), the number output by the randomness harvesting circuit 114 will not be a true random number.

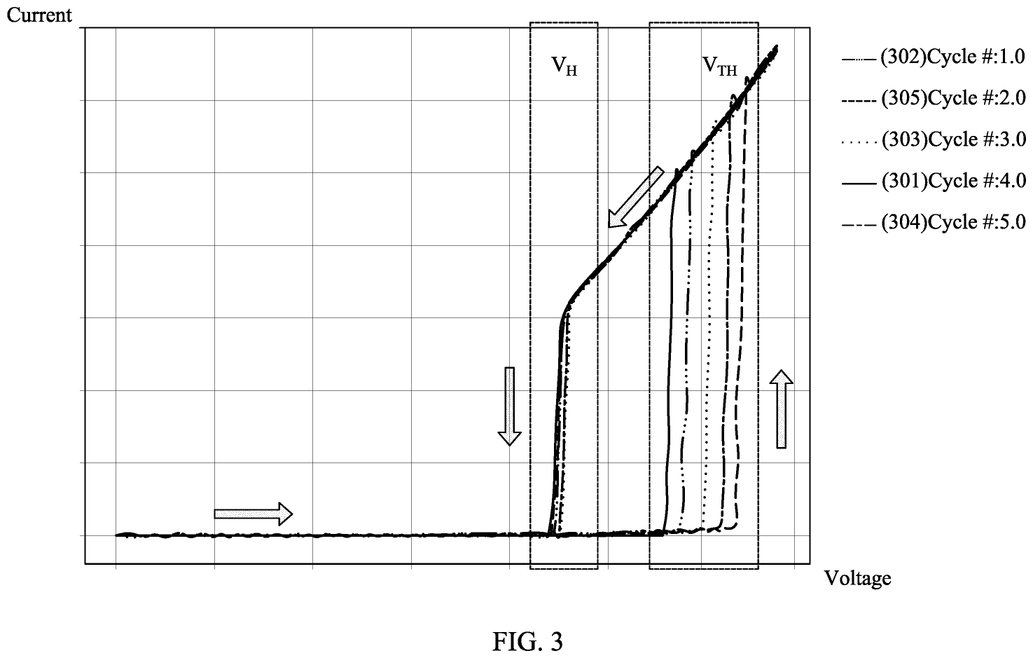

FIG. 3 is a diagram illustrating relationship curves between voltage and current of a selector device in accordance with an embodiment of the present disclosure.

In some embodiments, a selector device (or a volatile memory) switches between two states (ON and OFF) depending on the applied voltage. For example, the selector device may have a threshold voltage VTH and a hold voltage V_{H}. As the voltage applied to the selector device increases, the current of the selector device abruptly increases when the applied voltage reaches the threshold voltage VTH, as shown in the lower half portion of the curves 301 to 305. At this time, the selector device switches from the OFF state to the ON state. It should be noted that when the selector device is already in the ON state, the current of the selector device also increases with the applied voltage.

When the voltage applied to the selector device decreases from a first voltage higher than the threshold voltage, the selector device holds the ON state until the applied voltage drops below the hold voltage V_{H}, as shown in the higher half portion of the curves 301 to 305. At this time, the selector device switches from the ON state to the OFF state. It should be noted that FIG. 3 is an example of a specific selector technology but does not represent the behavior of every selector and volatile memory.

In some embodiments, the selector device (or selector, in short) may be regarded as a two-terminal component, and one terminal of the selector device may be connected to the voltage source, and the other terminal of the selector device may be connected to the ground or a node with a lower voltage level.

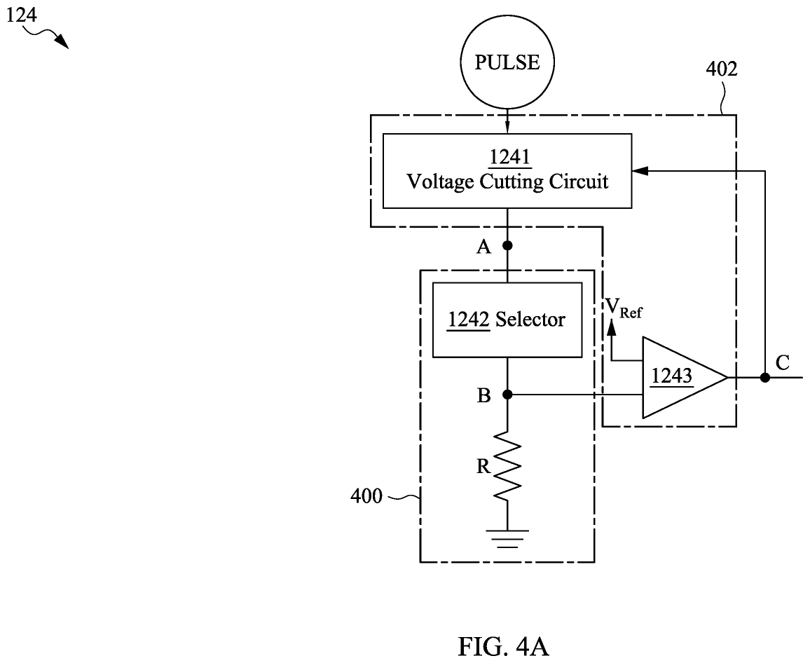

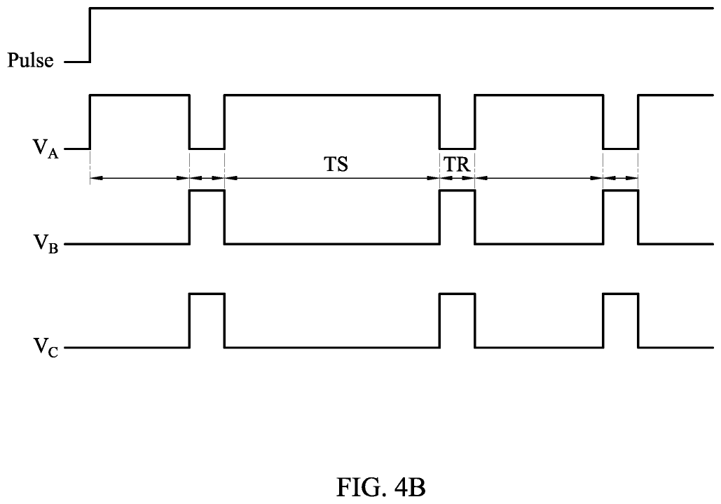

FIG. 4A is a schematic diagram of the randomness source circuit in accordance with a first embodiment of the present disclosure. FIG. 4B is a waveform diagram of the signals in various nodes in the randomness source circuit in accordance with the embodiment of FIG. 4A. Please refer to FIG. 1 and FIGS. 4A-4B.

In the first embodiment, the randomness source circuit 124 may be a voltage cutoff selector oscillator, which includes a voltage cutting circuit 1241, a selector 1242, and a comparator 1243. The voltage cutting circuit 1241 may be configured to control the voltage of a pulse signal transferred to the selector 1242 in response to the output oscillation signal at node C.

In some embodiments, the voltage cutting circuit 1241 may be implemented by a P-type transistor (not shown in FIG. 4A), which has a gate connected to node C, a source connected to the pulse signal, and a drain connected to the selector (i.e., node A). In response to the oscillation signal at node C being in the high logic state (i.e., logic 1), the P-type transistor is turned off, and the voltage of the pulse signal PULSE will not be transferred to the selector 1242. In response to the oscillation signal at node C being in the low logic state (i.e., logic 0), the P-type transistor is turned on, and the voltage of the pulse signal PULSE is transferred to the selector 1242. The pulse signal PULSE may be a fixed voltage higher than the reference voltage V_{Ref}.

For example, in response to the voltage V_{A} at node A being applied to the selector 1242, the selector 1242 is switched to the ON state after a certain switching time. The switching time TS of the selector 1242 depends on the technology used on the selector 1242. Specifically, the voltage of the pulse signal PULSE is transferred to node A when the voltage cutoff circuit is turned on (i.e., V_{C} is in the low logic state). Since the voltage applied to the selector 1242 is higher than the threshold voltage VTH of the selector 1242, the selector 1242 is turned on, and a current flows from the power supply voltage (not shown) to the ground through the voltage cutoff circuit 1241, the selector 1242, and the resistor R in sequence. Thus, the voltage V_{B} at node be will be higher than the reference voltage V_{Ref}, and the comparator 1243 will be switched to the high logic state at its output terminal (e.g., node C), so the voltage V_{C} at node C is kept at the power supply voltage (i.e., indicating logic 1) at this time. The voltage V_{C} at node C is fed back to the voltage cutoff circuit 1241, and the voltage cutoff circuit 1241 is turned off, so the voltage of the pulse signal PULSE will not be applied to the selector 1242.

When no voltage is applied to the selector 1242, the selector 1242 will switch back to the OFF state after a certain relaxation time TR, as shown in FIG. 4B. The relaxation time TR of the selector 1242 also depends on the technology used on the selector 1242.

In some embodiments, the components (e.g., comparator 1243 and voltage cutting circuit 1241) in block 402 can be fabricated in the front end of line since these components rely on transistors. In addition, the components (e.g., selector 1241 and resistor R) in block 400 can be fabricated in the back end of line since the selector 1241 may be part of the memory array 122 and the resistor R can be added in the back end of line.

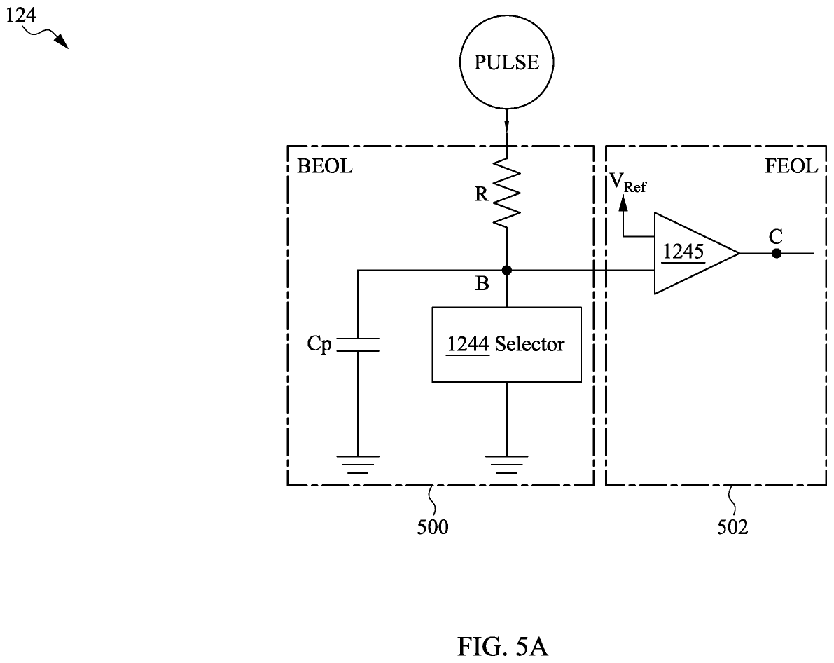

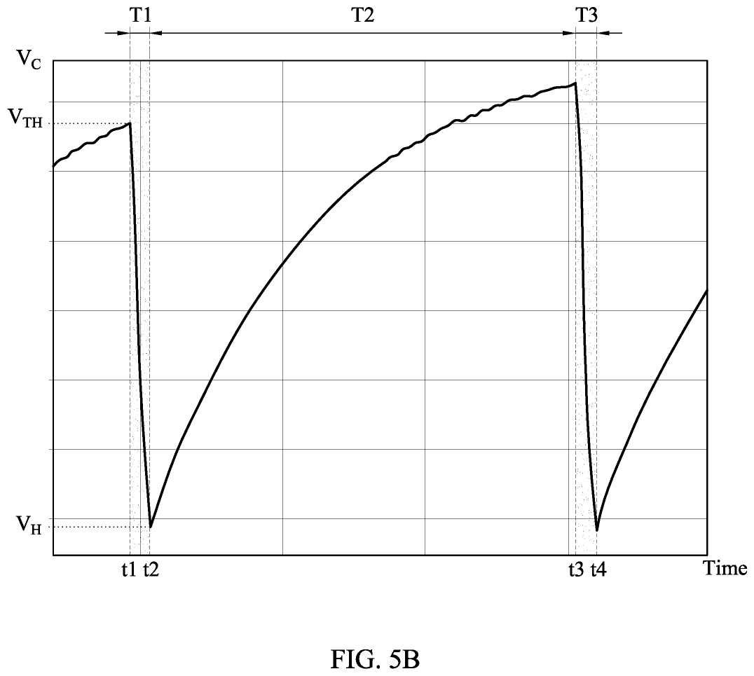

FIG. 5A is a schematic diagram of the randomness source circuit in accordance with a second embodiment of the present disclosure. FIG. 5B is a waveform diagram of the voltage V_{C} at the output terminal of the randomness source circuit in accordance with the embodiment of FIG. 5A. Please refer to FIG. 1 and FIGS. 5A-5B.

In the second embodiment, the randomness source circuit 124 may be implemented using the selector self-oscillation technique, and the self-oscillation circuit also provides oscillation signal required to generate randomness with the randomness harvesting circuit 114. For example, the randomness source circuit 124 may include a resistor R, a selector 1244, a parallel capacitor Cₚ, and a comparator 1245, as shown in FIG. 5A. A first terminal (e.g., node B) of the selector 1244 may be connected to the pulse signal PULSE through the resistor R, and a second terminal of the selector 1244 may be connected to the ground. In addition, the parallel capacitor Cₚ is disposed between node B and the ground, and it is parallel to the selector 1244.

Specifically, the selector 1244 may oscillate through the charging and discharging of the parallel capacitor Cₚ using the pulse signal PULSE, and the oscillation signal generated by the selector 1244 is then compared to the reference voltage V_{Ref} to generate an output oscillation signal between logic 1 and logic 0 at the output terminal (e.g., node C) of the randomness source circuit 124.

For example, given that node B is charged to the threshold voltage VTH of the selector 1244 through the parallel capacitor Cₚ at time t1, the selector 1244 is turned on (i.e., switching to the ON state). Meanwhile, the voltage V_{B} at node B is compared with the reference voltage V_{Ref}, and the oscillation signal output by the comparator 1245 is in the high logic state at the output terminal (e.g., node C) of the randomness source circuit 124. Since the selector 1244 switches to the ON state at time t1, a discharge current is induced from node B to the ground through the selector 1244 to discharge the parallel capacitor Cₚ. In addition, the discharge current abruptly increases when the selector 1244 is switched from the OFF state to the ON state, and thus the electrical charges stored in the parallel capacitor Cₚ are quickly discharged to the ground in a very short time, such as the period T1 between times t1 and t2. When the voltage V_{B} at node B is lower than then hold voltage V_{H} of the selector 1244 at time t2, the selector 1244 is turned off, and no current is allowed from node B to the ground through the selector 1244. Thus, the parallel capacitor Cₚ is charged again by the pulse signal PULSE from time t2 until the voltage V_{B} at node C reaches the threshold voltage VTH of the selector 1244, as shown by curve 510 in FIG. 5B. In other words, during the period T2 between times t2 and t3, the selector 1244 is in the OFF state, and the parallel capacitor Cₚ is charging.

It should be noted that the oscillation signal output by the comparator 1245 will be in the low logic state when the voltage V_{B} at node B is lower than the reference voltage V_{Ref} during discharge of the parallel capacitor Cₚ.

Similarly, when the voltage V_{B} at node B reaches the threshold voltage VTH of the selector 1244 through the parallel capacitor Cₚ at time t3, the selector 1244 is turned on (i.e., switching to the ON state). Meanwhile, the voltage V_{B} at node B is compared with the reference voltage V_{Ref}, and the oscillation signal output by the comparator 1245 is in the high logic state at the output terminal (e.g., node C) of the randomness source circuit 124. Since the selector 1244 switches to the ON state at time t3, a discharge current is induced from node B to the ground through the selector 1244 to discharge the parallel capacitor Cₚ, and the electrical charges stored in the parallel capacitor Cₚ are quickly discharged to the ground in a very short time, such as the period T3 between times t3 and t4. Accordingly, the aforementioned operations of the randomness source circuit 124 can be regarded as self-oscillation of the selector 1244, thereby generating oscillation for use by the randomness harvesting circuit 114.

In some embodiments, the comparator 1245 in block 502 may be fabricated in the front end of line, since the comparator 1245 relies on transistors. In addition, the components (e.g., resistor R, selector 1244, and parallel capacitor Cₚ) in block 500 may be fabricated in the back end of line since the selector 1244 may be part of the memory array 122, and the resistor R and the parallel capacitor Cₚ can be added in the back end of line.

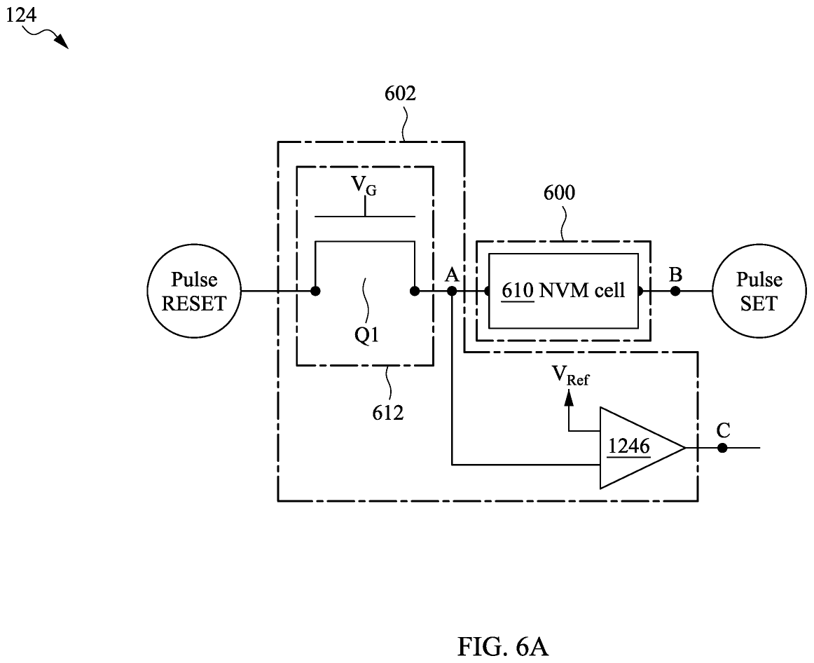

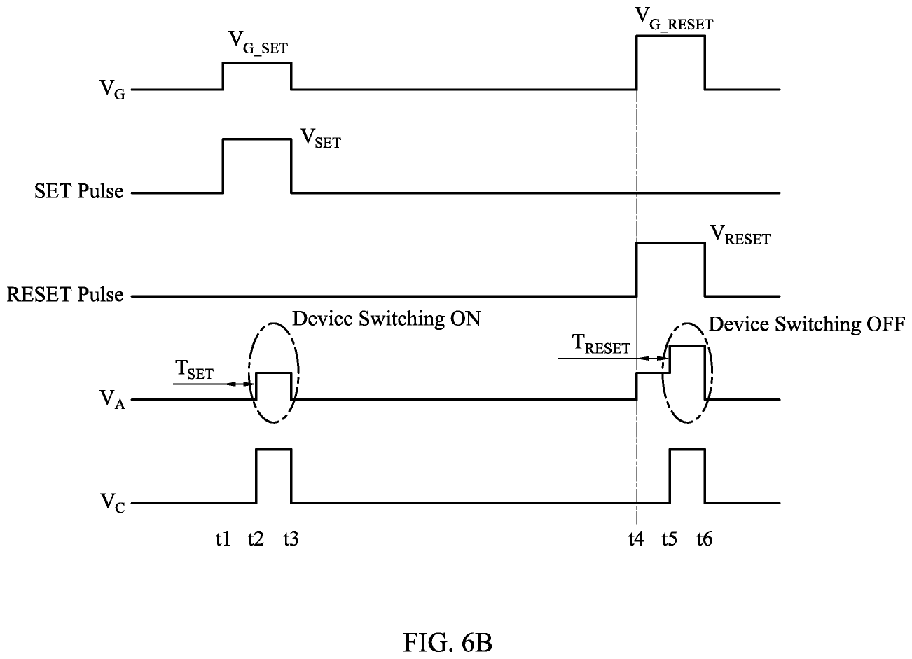

FIG. 6A is a schematic diagram of the randomness source circuit in accordance with a third embodiment of the present disclosure. FIG. 6B is a waveform diagram illustrating various signals in the randomness source circuit in accordance with the embodiment of FIG. 6A. Please refer to FIG. 1 and FIGS. 6A-6B.

In the third embodiment, the randomness source circuit 124 may be implemented by a non-volatile memory circuit. For example, the randomness source circuit 124 may include a switch circuit 612, a non-volatile memory (NVM) cell 610, and a comparator 1246. The non-volatile memory cell 610 may be implemented using a non-volatile memory having SET and RESET operations, such as RRAM (resistive RAM), PCRAM (phase change RAM), MRAM (magnetic RAM), or FeRAM (ferroelectric RAM), but the present disclosure is not limited thereto. In some embodiments, the switch circuit 612 may be implemented by an N-type transistor Q1, which has a gate connected to a gate voltage V_{G}, a first terminal connected to a first SET pulse signal, and a second terminal connected to node A. The non-volatile memory cell 610 may be regarded as a two-terminal component, which has a first terminal connected to node A, and a second terminal connected to a second SET pulse signal. The voltage V_{A} at node A is provided to one input terminal of the comparator 1246, and the comparator 1246 compares the voltage V_{A} with the reference voltage V_{Ref} to generate an oscillation signal at its output terminal (e.g., node C).

In some embodiments, for purposes of description, the non-volatile memory cell 610 may be implemented using an RRAM, and the gate voltage V_{G} and pulses signals SET and RESET are designed to accommodate the RRAM technology and ensure reliable SET and RESET switching. In addition, a shorter pulse of the pulse signals SET or RESET will lead to faster randomness generation during operations of the randomness source circuit 124.

In some embodiments, the amplitude of the gate voltage V_{G} and the pulse signals SET and RESET may range between 0.5V to 5V, and the duration for the pulse in these signals may range from Ins to 100 μs, but the present disclosure is not limited thereto. The ranges of the amplitude and duration of these signals can be extended depending on the technology and node used.

In addition, different reference voltages V_{Ref1} and V_{Ref2} (i.e., collectively shown as V_{Ref} in FIG. 6A) may be respectively used for the pulse signals SET and RESET to accommodate the difference in the voltage applied to the non-volatile memory cell 610 during the operations. In some embodiments, the first reference voltage V_{Ref1} may be lower than 40% of the set voltage V_{SET}, which is the voltage applied to the non-volatile memory cell 610 during the SET operation. The second reference voltage V_{Ref2} may be greater than 80% of the reset voltage V_{RESET}, as shown by the waveforms in FIG. 6B.

In addition, different voltages are also used for the gate voltage V_{G} for the SET and RESET operations, as shown in FIG. 6B. It should be noted that these values of the gate voltage depend on the type of non-volatile memory cell 610 and the technology used by the transistors of these components in the randomness source circuit 124, and they are designed to ensure that the state switching of the non-volatile memory cell 610 can be detected by the comparator 1246.

Referring to FIG. 6B, the SET pulse signal at node B is asserted to the high logic state at time t1, and the gate voltage V_{G} is set to the SET gate voltage V_{G_SET} in response to the SET pulse signal. The RESET pulse signal is kept at the low logic state at this time. After a set time T_{SET} from time t1, the voltage of the SET pulse signal is transferred to node A through the non-volatile memory cell 610, and the voltage V_{A} at node A goes to the high logic state (e.g., a first voltage level, V_{SET}) at time t2. Specifically, the voltage of the SET pulse signal at node B is higher than the voltage V_{A} at node A at time t2, the non-volatile memory cell 610 is turned on (i.e., switching to the ON state) after the set time T_{SET} in response to the SET pulse signal, and thus the voltage of the SET pulse signal is transferred to node A through the non-volatile memory cell 610.

Since the voltage V_{A} is higher than the first reference voltage V_{Ref1} for the SET operation, the voltage V_{C} at the output terminal (e.g., node C) of the comparator 1246 is switched to the high logic state (e.g., a second voltage level) at time t2. In response to the SET pulse signal is deasserted to the low logic state at time t3, the SET gate voltage V_{G_SET} is also set to 0V. Although the voltages at the two terminals (i.e., nodes A and B) of the non-volatile memory cell 610 are both 0V at time t3, the non-volatile memory cell 610 is still kept in the ON state because no reset signal is received by the non-volatile memory cell 610. Accordingly, at time t3, the voltage V_{A} at node A is lower than the first reference voltage for the SET operation, and the voltage V_{C} output by the comparator 1246 at node C also goes to the low logic state. It should be noted that the non-volatile memory cell 610 is kept in the ON state since time t3.

In addition, the RESET pulse signal is asserted to the high logic state (i.e., a third voltage level, V_{RESET}) at time t4, and the SET pulse signal is kept at the low logic state. The gate voltage V_{RESET} for the RESET operation also goes to the high logic state at time t4. It should be noted that a RESET time is required to reset the non-volatile memory cell 610, and the voltage V_{A} at node A is kept at a fourth voltage level higher than 0V during the RESET time T_{RESET}. Since the particular voltage level is lower than the second reference voltage V_{Ref2} for the reset operation, the voltage V_{C} output by the comparator 1246 at its output terminal (e.g., node C) is kept at the low logic state.

After the RESET time T_{RESET} from time t4, the non-volatile memory cell 610 is turned off (i.e., switching to the OFF state) at time t5 in response to the RESET pulse signal, and the voltage V_{A} at node A is switched to the high logic state (e.g., a fifth voltage level) at time t5. Since the fifth voltage level is higher than the second reference voltage V_{Ref2} for the RESET operation, the voltage V_{C} output by the comparator 1246 at its output terminal (e.g., node C) is switched to the high logic state at time t5.

At time t6, the RESET pulse signal is deasserted to the low logic state, and the gate voltage V_{G} RESET for the RESET operation also goes to the low logic state, and the switch circuit 612 is turned off. Thus, the voltage V_{A} at node A may be discharged to 0V at time t6, and the voltage V_{C} output by the comparator 1246 at its output terminal (e.g., node C) is switch to the low logic state at time t6, as shown in FIG. 6B. Therefore, the voltage V_{C} at the output terminal of the comparator 1246 can be regarded as an oscillation signal.

For purposes of description, in the embodiments of FIGS. 6A-6B, the first voltage level (i.e., V_{SET}) is lower than the third voltage level (i.e., V_{RESET}), and the fifth voltage level is higher than the second voltage level and the fourth voltage level. In addition, the second voltage level is substantially equal to the fourth voltage level. In addition, one of ordinary skill in the art will appreciate that the relationships between these voltage levels can be adjusted according to practical needs.

In some embodiments, the comparator 1246 and the switch circuit 612 in block 602 may be fabricated in the front end of line, since the comparator 1246 and switch circuit 612 rely on transistors. In addition, the components (e.g., NVM cell 610) in block 600 may be fabricated in the back end of line since the NVM cell 610 may be part of the memory array 122.

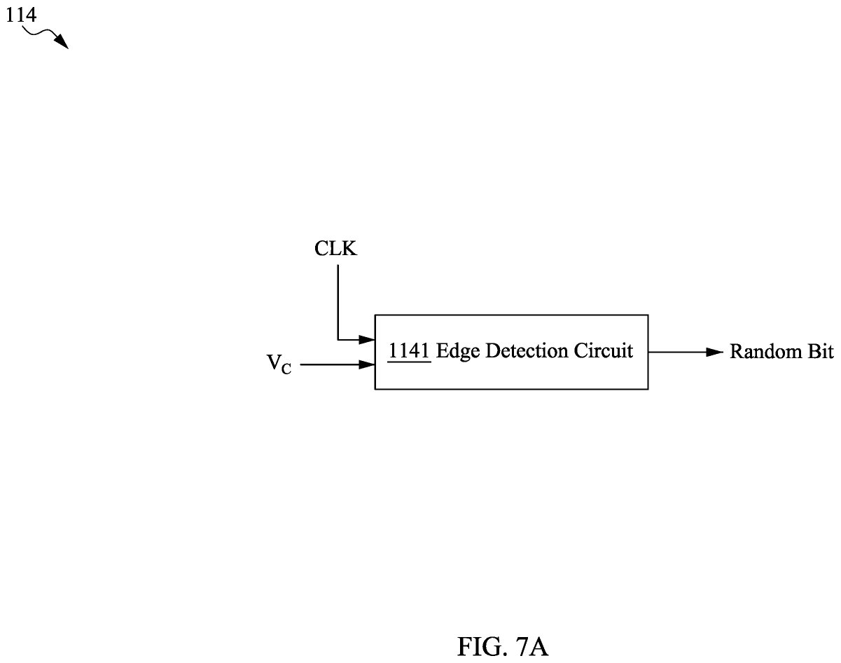

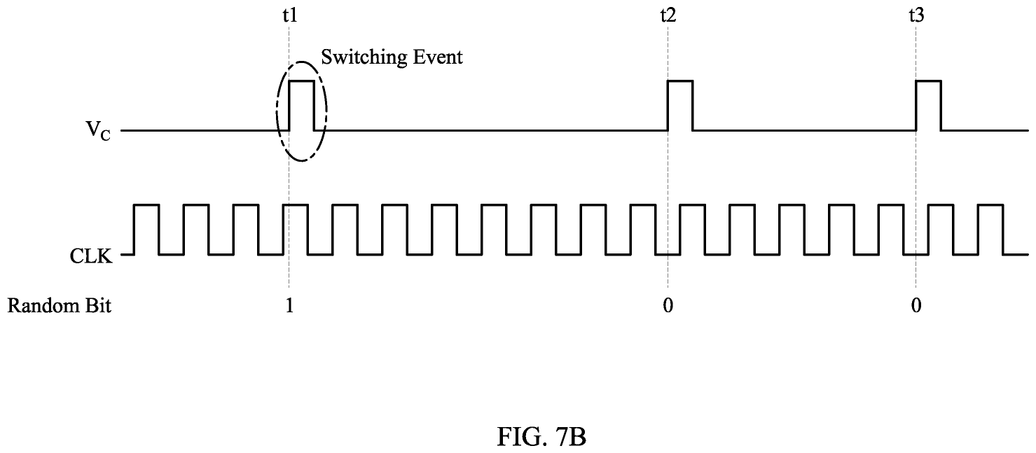

FIG. 7A is a block diagram of the randomness harvesting circuit 114 in accordance with an embodiment of the present disclosure. FIG. 7B is a diagram illustrating generation of random bits from the clock signal by the edge detection circuit in accordance with the embodiment of FIG. 7A. Please refer to FIG. 1 and FIGS. 7A-7B.

In some embodiments, the randomness harvesting circuit 114 may be configured to convert the oscillation signal generated by the randomness source circuit 124 to a bitstream of random numbers, and it may start with the oscillation signal from any of the randomness source circuits described in the embodiments of FIGS. 4 to 6. For example, the oscillation signal received by the randomness harvesting circuit 114 may be the voltage V_{C} generated by the randomness source circuit 124.

The randomness harvesting circuit 114 may include an edge detection circuit 1141, which receives the voltage V_{C} from the randomness source circuit 124 and the clock signal CLK. Since the voltage V_{C} is an oscillation signal switching between logic 0 and logic 1, the edge detection circuit 1141 may detect switching events of the oscillation signal (i.e., voltage V_{C}), such as rising edges and/or falling edges of the oscillation signal.

For purposes of description, the edge detection circuit 1141 in FIG. 7A detects rising edges of the oscillation signal (i.e., voltage V_{C}). For example, as shown in FIG. 7B, the edge detection circuit 1141 detects a first rising edge of the oscillation signal (i.e., voltage V_{C}) at time t1, and samples the clock signal CLK at time t1 to obtain a first random bit of “1”. The edge detection circuit 1141 detects a second rising edge of the oscillation signal (i.e., voltage V_{C}) at time t2, and samples the clock signal CLK at time t2 to obtain a second random bit of “0”. In addition, the edge detection circuit 1141 detects a third rising edge of the oscillation signal (i.e., voltage V_{C}) at time t3, and samples the clock signal CLK at time t3 to obtain a third random bit of “0”.

Specifically, the oscillation signal (i.e., voltage V_{C}) is generated based on the intrinsic features of the randomness source circuit 124, such as the switching time and relaxation time of the selector or non-volatile memory in the randomness source circuit 124. Thus, the random bits output by the randomness harvesting circuit 114 are truly random and constitute the true random number bitstream.

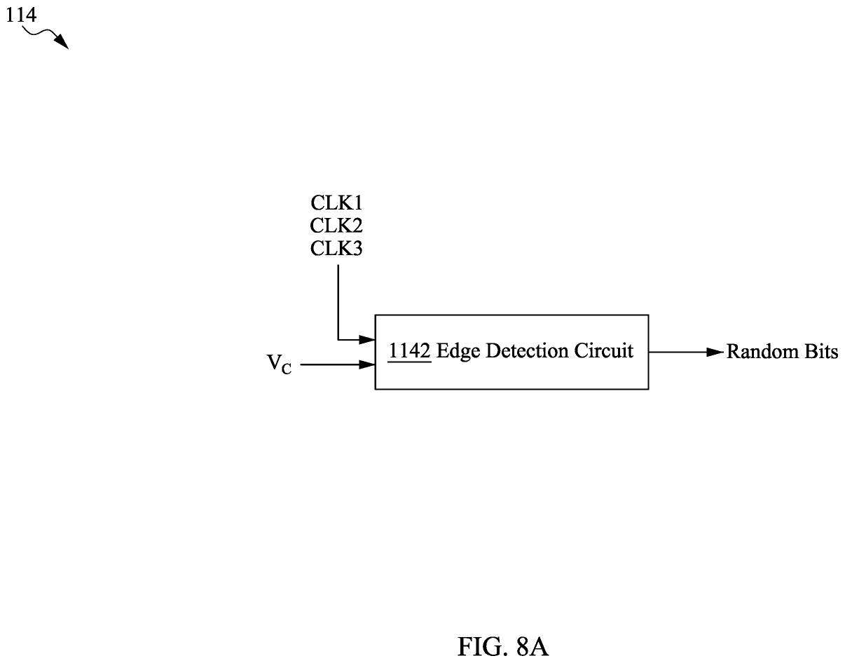

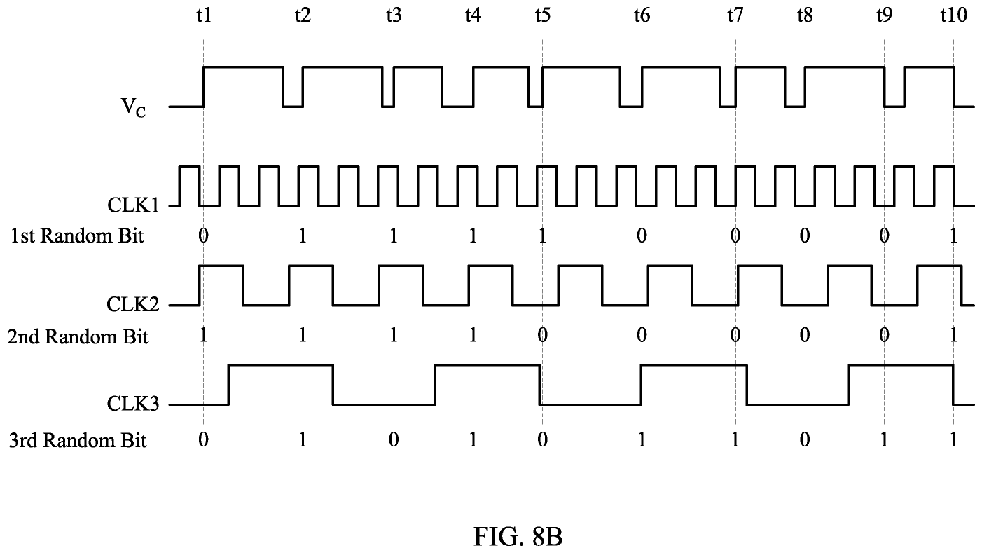

FIG. 8A is a block diagram of the randomness harvesting circuit 114 in accordance with another embodiment of the present disclosure. FIG. 8B is a diagram illustrating generation of random bits from multiple clock signals by the edge detection circuit in accordance with the embodiment of FIG. 8A. Please refer to FIG. 1 and FIGS. 8A-8B.

In some embodiments, the randomness harvesting circuit 114 may be configured to convert the oscillation signal generated by the randomness source circuit 124 to multiple bitstreams of random numbers, and it may start with the oscillation signal from any of the randomness source circuits described in the embodiments of FIGS. 4 to 6. For example, the randomness harvesting circuit 114 in FIG. 8A may include an edge detection circuit 1142, which receives the oscillation signal (i.e., voltage V_{C}) from the randomness source circuit 124 and multiple clock signals CLK1, CLK2, and CLK3.

For example, the clock signals CLK1, CLK2, and CLK3 can be used in parallel to increase the bit rate of the true random number generator, and to slow the degradation of the oscillation circuit (e.g., selector, volatile or non-volatile memory) of the true random number generator. Similarly, the edge detection circuit 1142 detects switching events of the oscillation signal, such as rising edges and/or falling edges of the oscillation signal. At every switching event detected, the value of every clock signal is output for an additional random number. In other words, for a single switching event detected, multiple random bits are generated. In addition, the generated random bits for each clock signal are stored in a buffer (not shown) which is periodically emptied to output a respective random number bitstream.

The period P of each clock signal N satisfies formula (1) so as to ensure true randomness of the true random number generator.

$${P}_{N} = {P}_{1} \times {X}^{N - 1} \qquad ( 1 )$$

where P1 the clock period of the fastest clock signal; X is an even integer (e.g., 2, 4, 6, . . . , etc.); N is a positive integer.

For example, given that the period of the fastest clock signal is 20 ns and X=2, the periods of the clock signals CLK1, CLK2, and CLK3 are 20 ns, 40 ns, and 80 ns, respectively. If the periods of the clock signals provided to the edge detection circuit 1142 do not satisfy formula 1, the bits generated by the edge detection circuit 1142 for each clock signal do not constitute a true random number. In some embodiments, the speed of the fastest clock signal is limited by the circuit capabilities, and the slowest clock signal is limited by cycle-to-cycle variation of the technology used by the randomness source circuit 124.

For purposes of description, three clock signals are shown in FIGS. 8A-8B, and the relationship between periods of the clock signals are described. One of ordinary skill in the art will appreciate that the edge detection circuit 1142 can receive two or more clock signals with different speeds. In addition, the overall bandwidth of the true random number generator increases with more clock signals provided to the randomness harvesting circuit 114.

Referring to FIG. 8B, when the edge detection circuit 1142 detects a first rising edge of the oscillation signal (i.e., voltage V_{C}), the edge detection circuit 1142 samples the clock signals CLK1, CLK2, and CLK3 to output a first random bit, a second random bit, and a third random bit as 0, 1, and 0, respectively. When the edge detection circuit 1142 detects a second rising edge of the oscillation (i.e., voltage V_{C}), the edge detection circuit 1142 samples the clock signals CLK1, CLK2, and CLK3 to output a first random bit, a second random bit, and a third random bit as 1, 1, and 1, respectively, and so on. In some embodiments, the generated first random bits, second random bits, and third random bits can constitute a first random number bitstream, a second random number bitstream, and a third random number bitstream, respectively. In some other embodiments, the generated first random bit, second random bit, and third random bit obtained at each switching event can collectively constitute one multi-bit random number, and the multi-bit random number obtained at each switching event constitute a true random number, which includes a sequence of random bits of 0, 1, 0, 1, 1, 1, 1, 1, 0, . . . , and so on.

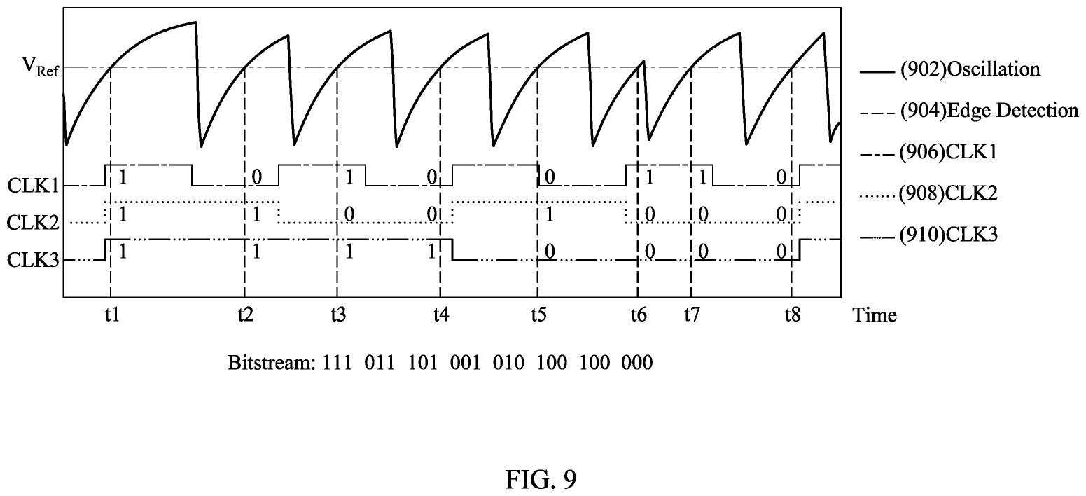

FIG. 9 is a waveform diagram of the oscillation signal and multiple clock signals in the randomness source circuit in accordance with the embodiment of FIG. 5A. Please refer to FIG. 5A and FIG. 9.

In some embodiments, when the randomness source circuit 124 is implemented using the selector self-oscillation technique, the edge detection circuit (not shown in FIG. 5A) of the randomness harvesting circuit 114 can receive the oscillation signal (i.e., curve 902) generated by the randomness source circuit 124 and multiple clock signals CLK1, CLK2, and CLK3 (i.e., curves 906, 908, and 910, respectively). The time points for detecting the switching events of the oscillation signal are shown by lines 904. Specifically, when the voltage level of the oscillation signal reaches the reference voltage V_{Ref} at time t1 during the first rising edge of the oscillation signal, the output signal of the comparator 1245 will be in the high logic state (i.e., logic 1). The edge detection circuit will detect a first switching event (i.e., first rising edge) of the oscillation signal at time t1, and sample the clock signals CLK1, CLK2, and CLK3 at time t1 to obtain a random bit of 1, 1, and 1, respectively. In other words, three random bits can be obtained at the first switching event.

When the voltage level of the oscillation signal reaches the reference voltage V_{Ref} at time t2 during the second rising edge of the oscillation signal, the output signal of the comparator 1245 will be in the high logic state (i.e., logic 1). The edge detection circuit will detect a second switching event (i.e., second rising edge) of the oscillation signal at time t2, and sample the clock signals CLK1, CLK2, and CLK3 at time t1 to obtain a random bit of 0, 1, and 1, respectively. Similarly, when the voltage level of the oscillation signal reaches the reference voltage V_{Ref} at time t2 during the third rising edge of the oscillation signal, the output signal of the comparator 1245 will be in the high logic state (i.e., logic 1). The edge detection circuit will detect a third switching event (i.e., third rising edge) of the oscillation signal at time t3, and sample the clock signals CLK1, CLK2, and CLK3 at time t1 to obtain a random bit of 1, 0, and 1, respectively. The random bits obtained at every switching event (e.g., rising edges) of the oscillation signal can be obtained in a similar manner, and they can be output in sequence to obtain a random number sequence, as shown in FIG. 9.

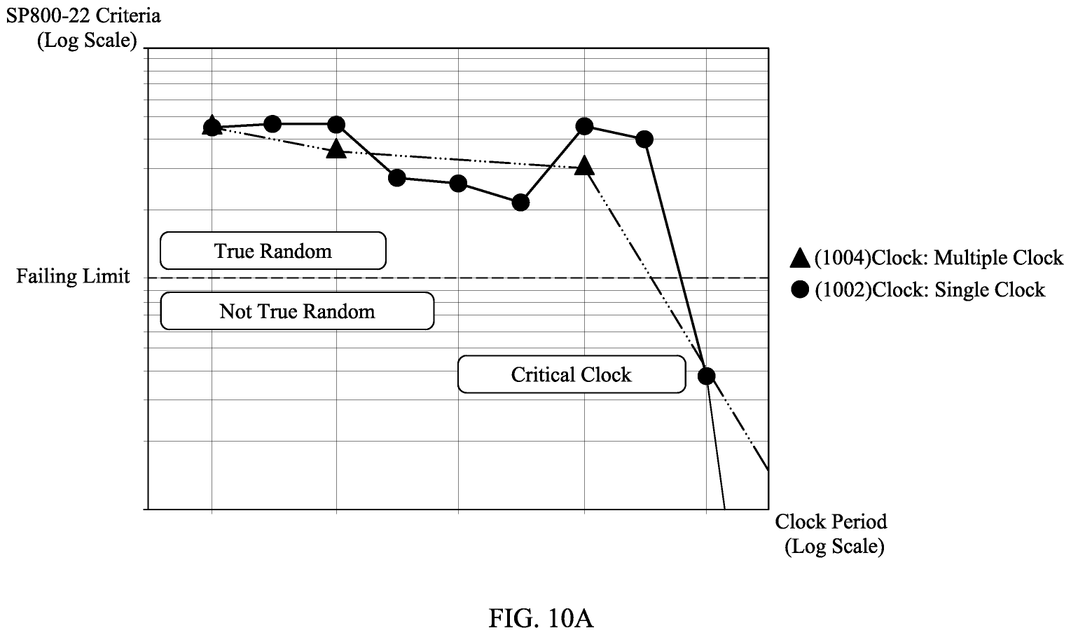

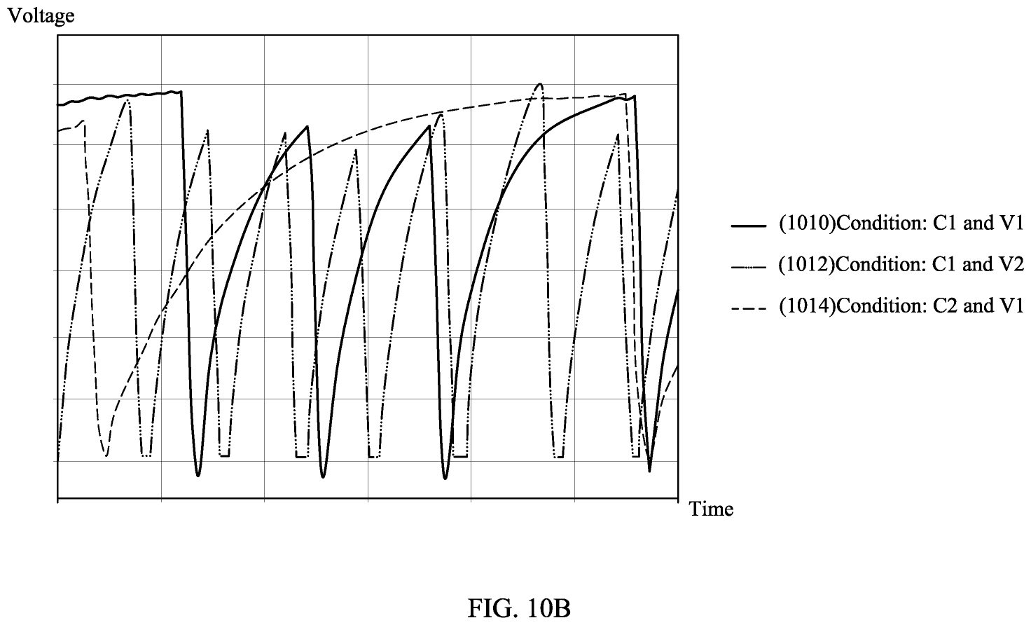

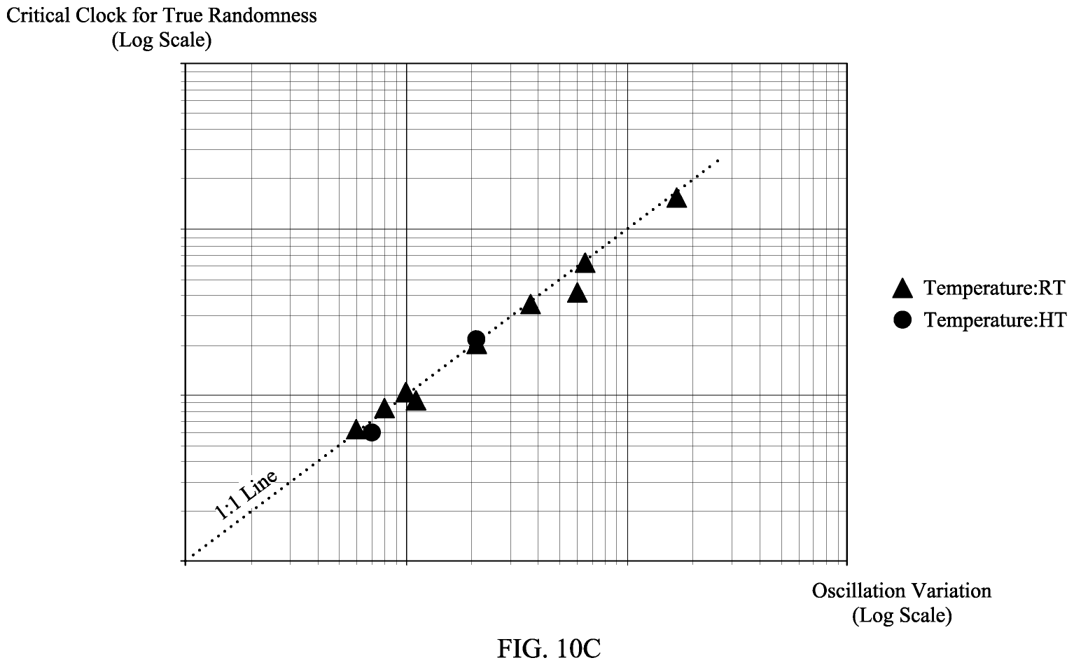

FIG. 10A is a diagram illustrating relationships between the SP800-22 measured value and clock period in accordance with the embodiment of FIG. 9. Please refer to FIG. 9 and FIG. 10A.

In some embodiments, the randomness of the true random number generator (i.e., the randomness source circuit 124 plus the randomness harvesting circuit 114) of the present application can be measured by the “SP800-22” which is a statistical test suite for random and pseudorandom number generators for cryptographic applications developed by the National Institute of Standards and Technology (NIST) of the U.S. Department of Commerce. For example, the test items of the SP800-22 test suite may include frequency, block frequency, runs, longest run of ones, matrix rank, discrete Fourier transform, non-overlapping template, overlapping template, universal, linear complexity, serial, approximate entropy, cumulative sums test (forward), cumulative sums test (backward), random excursions, and random excursions variant, etc.

The true random number generator of the present application is assessed via the SP800-22 test suite respectively at room temperature (e.g., 25° C.) and a high temperature (e.g., 120° C.), and the test results shows that the true random number generator passes the aforementioned test items at room temperature and the high temperature.

Referring to FIG. 10A, the measurement results of the true random number generator of the present application are shown by curves 1004 and 1002. For example, curve 1004 includes various points measured by the SP800-22 criteria at different clock periods for a single clock signal used by the randomness harvesting circuit 114, and curve 1002 includes various points measured by the SP800-22 criteria at different clock periods for three different clock signals used by the randomness harvesting circuit 114.

When the value measured by the SP800-22 test suite for a given clock period is above the failing limit, the random number generator can be regarded as true random for the given clock period. When the value measured by the SP800-22 test suite for a given clock period is under the failing limit, the random number generator can be regarded as not true random for the given clock period. Test results of the SP800-22 test suite in curves 1004 and 1002 in FIG. 10A have shown that the random numbers output by the true random number generator of the present application are truly random for a wide range of clock periods (i.e., in log scale). In addition, when the clock period is very large, the test result of the SP800-22 test suite falls under the failing limit, and it indicates that the random number generated by the true random number generator is not truly random for the very large clock period as shown in FIG. 10A, and this clock period can be regarded as the clock period of the critical clock signal.

FIG. 10B is a diagram illustrating the relationships between the voltage and time using different parallel capacitors and voltages in accordance with the embodiment of FIG. 9.

Referring to FIG. 10B, the oscillation signal generated by the randomness harvesting circuit 114 can be controlled by tuning the capacitance of the parallel capacitor Cₚ and the voltage of the pulse signal PULSE. In FIG. 10B, two capacitances C1 and C2 along with two voltages V1 and V2 are shown. For example, curve 1010 denotes the oscillation signal using the capacitance C1 and voltage V1, and curve 1012 denotes the oscillation signal using the capacitance C1 and voltage V2, and curve 1014 denotes the oscillation signal using the capacitance C2 and voltage V1. It should be noted that the capacitances and voltages used in FIG. 10B are for purposes of description, and one of ordinary skill in the art could adjust the number of capacitances and voltages used to control the oscillation signal generated by the randomness harvesting circuit 114.

FIG. 10C is a diagram illustrating relationships between the critical clock for true randomness and the oscillation variation in accordance with the embodiment of FIG. 9.

In some embodiments, the conditions of the true random number generator can be tuned to reach a large scale of oscillation variation which refers to the period difference between two consecutive oscillations, and the test results shows that the critical clock for true randomness matches the oscillation variations one to one at both the room temperature (e.g., 25° C.) and high temperature (e.g., 100° C.).

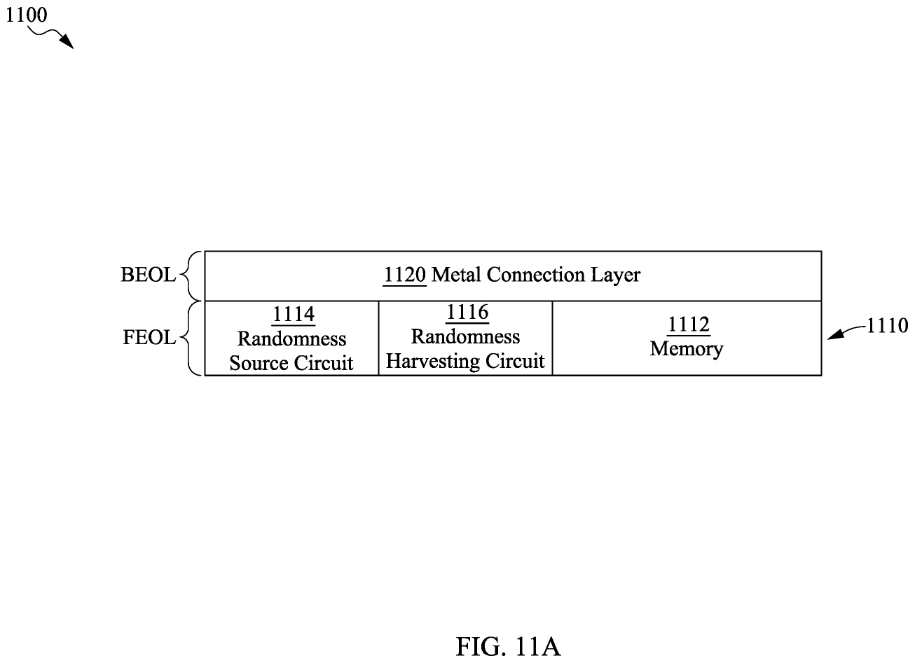

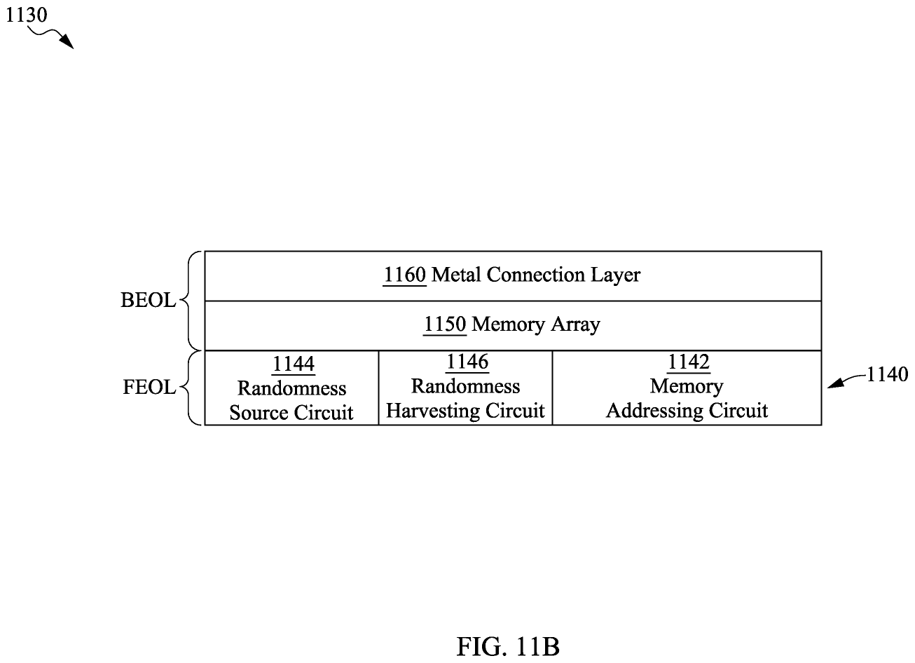

FIGS. 11A-11B are block diagrams of the true random number generator in accordance with different comparative embodiments of the present disclosure. Please refer to FIG. 1 and FIGS. 11A-11B.

In some embodiments, the memory device 1100 may include a memory 1112 (e.g., a flash memory), a randomness source circuit 1114, a randomness harvesting circuit 1116, and a metal connection layer 1120, as shown in FIG. 11A. The memory 1112, randomness source circuit 1114, and randomness harvesting circuit 1116 may be fabricated on a die 1110. The randomness source circuit 1114 may be implemented using a ring oscillator which include an odd number of inverters (i.e., NOT gates). Since inverters are made of transistors, the ring oscillator is integrated into the front end of line. The oscillation variation of the ring oscillator is random, and the randomness is then harvested by an additional circuit such as the randomness harvesting circuit 1116, and the randomness harvesting circuit 1116 is also integrated in the front end of line. The main advantage of the ring oscillator is the high bit rate of the randomness generation and its infinite lifetime. However, it is costly in term of FEOL footprint. This cost leads to a trade-off between integrating the ring oscillator close to the memory 1112 to improve speed and security or to integrate the ring oscillator in a separate chip to reduce cost.

In some other embodiments, the memory device 1130 includes a memory addressing circuit 1142, a randomness source circuit 1144, and a randomness harvesting circuit 1146, a memory array 1150, and a metal connection layer 1160, as shown in FIG. 11B. The memory addressing circuit 1142, randomness source circuit 114, and randomness harvesting circuit 1146 may be fabricated on a die 1140 (e.g., a logic die). The memory array 1150 (e.g., a memory die) may be vertically stacked on and bond to the die 1140 using a 3D-stacked memory technique. The randomness source circuit 1144 may be implemented using a ring oscillator which includes an odd number of inverters (i.e., NOT gates). Since inverters are made of transistors, the ring oscillator is integrated into the front end of line. The oscillation variation of the ring oscillator is random, and the randomness is then harvested by an additional circuit such as the randomness harvesting circuit 1146, and the randomness harvesting circuit 1146 is also integrated in the front end of line.

Referring to FIG. 1, since the randomness source circuit 124 is integrated in the back end of line to reduce the footprint, the randomness source circuit 124 of the true random number generator can be placed adjacent to the memory array 122 or directly inside the memory array 122 due to small footprint. In addition, the true random number generator (i.e., randomness source circuit 124 plus the randomness harvesting circuit 114) in FIG. 1 can provide asynchronic randomness generation for better security, faster speed, and better lifetime than the memory devices 1100 and 1130 in FIGS. 11A-11B, and the it has lower power consumption per generated bit (e.g., 10 times lower). Moreover, the true random number generator in FIG. 1 does not need additional circuitry for probability tracking, randomness correction, etc., and this improves the security of the semiconductor device 100 using the 3D-stacked memory technique.

In some embodiments, parallelization is possible for the semiconductor device 100 in the back end of line, and the cost of the front end of line can be reduced. In addition, multiple clock signals with different frequencies can be used by the randomness harvesting circuit 114 to achieve a higher bitrate of the random number.

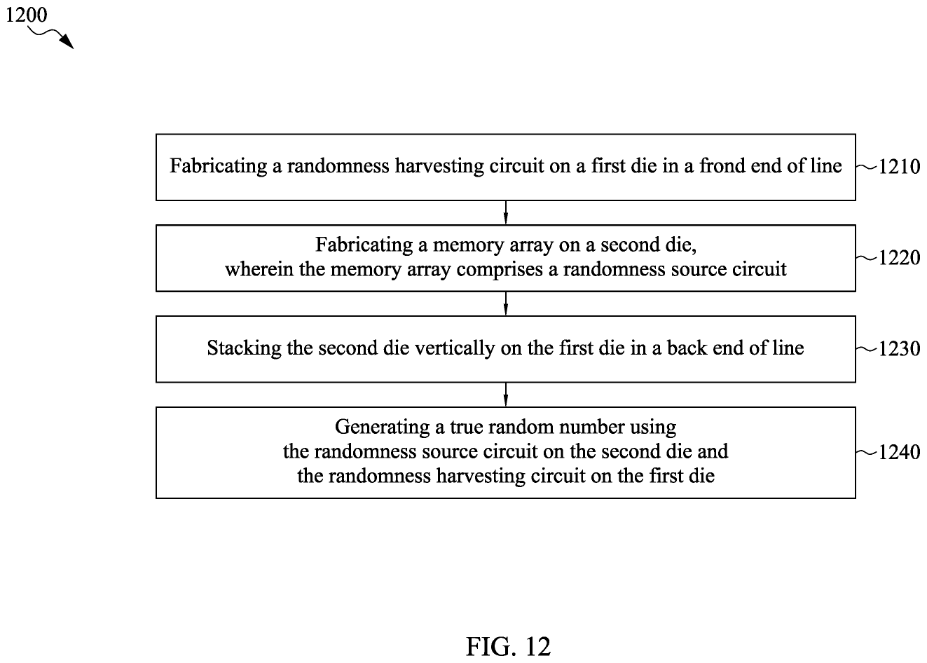

FIG. 12 is a flowchart of a method for fabricating a semiconductor device in accordance with an embodiment of the present disclosure. Please refer to FIG. 1 and FIG. 12.

In operation 1210, a randomness harvesting circuit 114 and a memory addressing circuit 112 are fabricated on a first die 110 in a front end of line. For example, the memory addressing circuit 112 may be an address decoding circuit that is configured to select memory cells in the memory array 122 in response to a memory address indicated by a memory command. The randomness harvesting circuit 114 may be configured to convert the oscillation signal generated by the randomness source circuit 124 into a bitstream of random numbers.

In operation 1220, a memory array 122 is fabricated on a second die 120, wherein the memory array 122 comprises a randomness source circuit 124. For example, the memory array 122 may be implemented using one of non-volatile memory, such as MRAM (magnetic RAM), PCRAM (phase change RAM), RRAM (resistive RAM), flash memory, etc., but the present disclosure is not limited thereto.

In operation 1230, the second die is stacked on and bond to the first die in a back end of line. For example, the first die 110 and the second die 120 can be fabricated individually. The second die 120 can be vertically stacked on and bond to the first die 110 using the 3D-stacked memory technique in the back end of line.

In operation 1240, a true random number is generated using the randomness source circuit on the second die and the randomness harvesting circuit on the first die. For example, since the randomness source circuit 124 may be part of the memory array 122, the footprint of the true random number generator can be reduced to a small extent. In addition, the randomness harvesting circuit 114 may detect switching events (e.g., rising edges and/or falling edges) of the oscillation signal generated by the randomness source circuit 124 to generate random bits. In addition, the generated random bits can be stored in a buffer, and output in a random number bitstream.

In an embodiment, the present disclosure provides a semiconductor device, which includes a first die and a second die. The first die includes a randomness harvesting circuit. The second die includes a memory array, and the second die is vertically stacked on the first die. The memory array includes a randomness source circuit, and a true random number is generated using the randomness source circuit on the second die and the randomness harvesting circuit on the first die.

In another embodiment, the present disclosure provides a true random number generator, which includes a randomness harvesting circuit and a randomness source circuit. The randomness harvesting circuit is disposed on a first die of a semiconductor device. The randomness source circuit is disposed on a second die of the semiconductor device, and configured to generate an oscillation signal. The randomness harvesting circuit is configured to convert the oscillation signal to one or more random bits that constitute a random number bitstream, wherein the second die is vertically stacked on the first die.

In yet another embodiment, the present disclosure provides a method for fabricating a semiconductor device. The method includes fabricating a randomness harvesting circuit on a first die in a front end of line, fabricating a memory array on a second die, wherein the memory array comprises a randomness source circuit, stacking the second die on the first die in a back end of line, and generating a true random number using the randomness source on the second die and the harvesting circuit on the first die.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A semiconductor device, comprising:
a first die, comprising a randomness harvesting circuit; and
a second die, comprising a memory array, wherein the second die is vertically stacked on the first die, and the memory array comprises a randomness source circuit;
wherein the randomness source circuit on the second die and the randomness harvesting circuit on the first die are configured to generate a true random number.

2. The semiconductor device of claim 1, wherein the first die further comprises a memory addressing circuit configured to select memory cells in the memory array in response to a memory address indicated by a memory command.

3. The semiconductor device of claim 2, wherein the memory addressing circuit and the randomness harvesting circuit on the first die are fabricated in a front end of line, and the second die is vertically stacked on the first die in a back end of line.

4. The semiconductor device of claim 3, wherein the randomness source circuit is configured to generate an oscillation signal based on intrinsic features of a selector device or a memory cell, and the randomness harvesting circuit is configured to samples one or more clock signals in response to detecting a switching event of the oscillation signal to generate one or more random bits.

5. The semiconductor device of claim 1, wherein the randomness source circuit comprises a voltage cutting circuit, a selector device, and a comparator,
wherein the voltage cutting circuit is configured to be turned on or off in response to an oscillation signal at an output terminal of the comparator,
wherein the selector device is configured to receive a first voltage of a pulse signal from a first node in response to the voltage cutting circuit being turned on.

6. The semiconductor device of claim 5, wherein in response to the first voltage being higher than a threshold voltage of the selector device, the selector device is turned on after a switching time, and a current flowing through a second terminal of the selector device and a resistor generates a second voltage at a first input terminal of the comparator,
wherein the comparator compares the second voltage with a reference voltage received at a second input terminal to generate the oscillation signal.

7. The semiconductor device of claim 6, wherein in response to the second voltage being higher than or equal to the reference voltage, the oscillation signal generated by the comparator is in a high logic state,
wherein in response to the second voltage being lower than the reference voltage, the oscillation signal generated by the comparator is in a low logic state.

8. The semiconductor device of claim 7, wherein in response to the oscillation signal generated by the comparator being in the low logic state, the voltage cutting circuit is turned off to stop providing the first voltage of the pulse signal to the selector device, and the selector device is turned off after a relaxation time.

9. The semiconductor device of claim 1, wherein the randomness source circuit comprises a selector device, a parallel capacitor, and a comparator,
wherein the selector device and the parallel capacitor are coupled between a first node and a ground, and receive a pulse signal at the first node through a resistor,
wherein the comparator compares a first voltage at the first node and a reference voltage to generate an oscillation signal.

10. The semiconductor device of claim 9, wherein in response to the first voltage at the first node being lower than a threshold voltage of the selector device, the selector device is turned off, and the parallel capacitor is charged to a second voltage of the pulse signal through the resistor,
wherein in response to the first voltage at the first node being higher than a threshold voltage of the selector device, the selector device is turned on to discharge the parallel capacitor.

11. The semiconductor device of claim 1, wherein the randomness source circuit comprises a non-volatile memory cell, a switch circuit, and a comparator,
wherein the non-volatile memory cell is coupled between a set pulse signal and a first node, and the switch circuit is coupled between a reset pulse signal and the first node,
wherein the comparator is configured to compare a first voltage at the first node with a reference voltage to generate an oscillation circuit.

12. The semiconductor device of claim 11, wherein in response to the set pulse signal being asserted to a high logic state, the non-volatile memory cell is turned on after a set time, and the first voltage at the first node goes to a first voltage level higher than a first reference voltage, and the comparator compares the first voltage level with the first reference voltage to output an oscillation signal at the high logic state;
wherein in response to the reset pulse signal being asserted to a second voltage level, the non-volatile memory cell is turned off after a reset time, and the first voltage at the first node goes to a second voltage level lower than a second reference voltage, and the comparator compares the second voltage level with the second reference voltage to output the oscillation signal at the low logic state;
wherein the first voltage level is lower than the second voltage level.

13. A true random number generator, comprising:
a randomness harvesting circuit, disposed on a first die of a semiconductor device; and
a randomness source circuit, disposed on a second die of the semiconductor device, and configured to generate an oscillation signal;
wherein the randomness harvesting circuit is configured to convert the oscillation signal into one or more random bits that constitute a random number bitstream,
wherein the second die is vertically stacked on the first die.

14. The true random number generator of claim 13, wherein the first die further comprises a memory addressing circuit configured to select memory cells in a memory array fabricated on the second die in response to a memory address indicated by a memory command, and the memory addressing circuit and the randomness harvesting circuit on the first die are fabricated in a front end of line.

15. The true random number generator of claim 14, wherein the randomness source circuit is a selector device or a memory cell in the memory array, and the second die is vertically stacked on the first die in a back end of line.

16. A method for fabricating a semiconductor device, the method comprising:
fabricating a randomness harvesting circuit on a first die in a front end of line;
fabricating a memory array on a second die, wherein the memory array comprises a randomness source circuit;
stacking the second die on the first die in a back end of line;
wherein the randomness source circuit on the second die and the randomness harvesting circuit on the first die are configured to generate a true random number.

17. The method of claim 16, wherein the first die further comprises a memory addressing circuit configured to select memory cells in the memory array in response to a memory address indicated by a memory command.

18. The method of claim 17, further comprising:
generating an oscillation signal based on intrinsic features of a selector device or a memory cell of the randomness source circuit; and
sampling one or more clock signals in response to detecting a switching event of the oscillation signal to generate one or more random bits.

19. The method of claim 18, wherein the switching event indicates a rising edge and/or a falling edge of the oscillation signal.

20. The method of claim 18, further comprising:
storing the generated one or more random bits in a buffer; and
outputting the random bits stored in the buffer in a random number bitstream.
